(19) United States
(12) Patent Application Publication
(10) Pub. No.: US 2025/0072044 A1
(43) Pub. Date: Feb. 27, 2025

(54) POWER SEMICONDUCTOR DEVICES HAVING GATE TRENCHES WITH ASYMMETRICALLY ROUNDED UPPER AND LOWER TRENCH CORNERS AND/OR RECESSED GATE ELECTRODES AND METHODS OF FABRICATING SUCH DEVICES

(71) Applicant: Wolfspeed, Inc., Durham, NC (US)

(72) Inventors: Woongsun Kim, Cary, NC (US); Matthew N. McCain, Raleigh, NC (US); Naeem Islam, Morrisville, NC (US); Madankumar Sampath, Cary, NC (US); Sei-Hyung Ryu, Cary, NC (US)

(21) Appl. No.: 18/453,414

(22) Filed: Aug. 22, 2023

(51) Int. Cl. H01L 29/78; H01L 29/16; H01L 29/423; H01L 29/66; H01L 29/739

(52) U.S. Cl. CPC H01L 29/7813; H01L 29/1608; H01L 29/4236; H01L 29/42368; H01L 29/66348; H01L 29/66734; H01L 29/7397

(57) ABSTRACT

A semiconductor device comprises a silicon carbide based semiconductor layer structure that comprises an active region. A gate trench is provided in an upper portion of the semiconductor layer structure, the gate trench having a first rounded lower corner and a second rounded lower corner. A gate electrode is provided in the gate trench. Within the active region, an upper surface of the gate electrode is below or coplanar with an upper surface of the semiconductor layer structure.

### FIELD

The present invention relates to power semiconductor devices and, more particularly, to power semiconductor devices having gate trenches and to methods of fabricating such devices.

### BACKGROUND

The Metal Oxide Semiconductor Field Effect Transistor (“MOSFET”) is a well-known type of semiconductor device that may be used as a switch. A MOSFET is a three terminal device that has gate, drain and source terminals and a semiconductor body. The semiconductor body is referred to herein as a “semiconductor layer structure.” A source region and a drain region are formed in the semiconductor layer structure that are separated by a channel region, and a gate electrode (which may act as the gate terminal or be electrically connected to the gate terminal) is disposed adjacent the channel region and separated from the channel region by a thin oxide layer that insulates the gate electrode from the channel region. A MOSFET may be turned on or off by setting a bias voltage that is applied to the gate electrode to be above or below a threshold value. When a MOSFET is turned on (i.e., it is in its “on-state”), current is conducted through the channel region of the MOSFET between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch a MOSFET between its on-state and its off-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate. A semiconductor layer structure may include one or more semiconductor layers, such as semiconductor substrates and/or semiconductor epitaxial layers.

The semiconductor layer structure of a power semiconductor device typically includes an “active region” in which one or more functional semiconductor devices are formed. The active region acts as a main junction for blocking voltage during reverse bias (off-state) operation and providing current flow during forward bias (on-state) operation. The power semiconductor device may also have an edge termination in a termination region of the semiconductor layer structure that is adjacent (and typically surrounding) the active region. Typically, multiple power semiconductor devices are formed in/on a common wafer, and each power semiconductor device will typically have its own edge termination. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a standard gate electrode design in which the gate electrode of the transistor is formed on top of the semiconductor layer structure or, alternatively, may have the gate electrode buried in a gate trench within the semiconductor layer structure. MOSFETs having buried gate electrodes are typically referred to as gate trench MOSFETs. With the standard gate electrode design, the channel region of each unit cell transistor is horizontally disposed underneath the gate electrode. In contrast, in the gate trench MOSFET design, the channels are typically vertically disposed. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to embodiments of the present invention, semiconductor devices are provided that include a silicon carbide based semiconductor layer structure that comprises an active region. A gate trench is provided in an upper portion of the semiconductor layer structure, the gate trench having a first rounded lower corner and a second rounded lower corner. A gate electrode is provided in the gate trench. Within the active region, an upper surface of the gate electrode is below or coplanar with an upper surface of the semiconductor layer structure. The gate trench also has a first rounded upper corner and a second rounded upper corner.

In some embodiments, a radius of curvature of the first rounded lower corner exceeds a radius of curvature of the first rounded upper corner. In some embodiments, a radius of curvature of the first rounded lower corner is at least twice a radius of curvature of the first rounded upper corner.

In some embodiments, the upper surface of the gate electrode is below the upper surface of the semiconductor layer structure. In some embodiments, the upper surface of the gate electrode is below a midpoint of an arc defined by the first rounded upper corner. In some embodiments, the upper surface of the gate electrode is below a location where the first rounded upper corner has a smallest instantaneous angle. In some embodiments, the upper surface of the gate electrode is at least 0.1 microns below the location where the first rounded upper corner has the smallest instantaneous angle.

In some embodiments, the semiconductor layer structure further comprises a termination region that surrounds the active region, and the portion of the semiconductor layer in the active region comprises a drift region having a first conductivity type, a plurality of well regions having a second conductivity type that is different from the first conductivity type on the drift region, and a plurality of source regions having the first conductivity type, each source region in an upper portion of respective one of the well regions. In some embodiments, the semiconductor device may further comprise a plurality of additional gate trenches in the upper surface of the semiconductor layer structure, a plurality of additional gate electrodes in the respective plurality of additional gate trenches, where an upper surface of a portion of each additional gate electrode that is within the active region is below the upper surface of the semiconductor layer structure, a gate dielectric layer in the gate trench between the gate electrode and the semiconductor layer structure, and a plurality of additional gate dielectric layers in the respective additional gate trenches between the respective additional gate electrodes and the semiconductor layer structure.

The semiconductor device may also comprise a gate dielectric layer in the gate trench between the gate electrode and the semiconductor layer structure, and the semiconductor device may be configured so that during on-state operation a peak electric field value in the gate dielectric layer will be located in a portion of the gate dielectric layer that is below the upper surface of the semiconductor layer structure.

In some embodiments, the semiconductor device is a Metal Oxide Semiconductor Field Effect Transistor (“MOSFET”) or an insulated Gate Bipolar Transistor (“IGBT”).

Pursuant to further embodiments of the present invention, semiconductor devices are provided that include a silicon carbide based semiconductor layer structure that comprises an active region. A gate trench is provided in an upper portion of the semiconductor layer structure, the gate trench having a first rounded lower corner, a second rounded lower corner, a first rounded upper corner and a second rounded upper corner. A gate electrode is provided in the gate trench. A respective radius of curvature of the first rounded lower corner exceeds a respective radius of curvature of the first rounded upper corner.

In some embodiments, a first portion of the gate electrode is within the active region and a second portion of the gate electrode is outside the active region, and wherein an upper surface of the first portion of the gate electrode is below or coplanar with the upper surface of the semiconductor layer structure. In some embodiments, the upper surface of the gate electrode is below the upper surface of the semiconductor layer structure. In some embodiments, the upper surface of the first portion of the gate electrode is below a midpoint of an arc defined by the rounded upper corner of the gate trench. In some embodiments, the upper surface of the first portion of the gate electrode is lower than a location where the first rounded upper corner has a smallest instantaneous angle.

In some embodiments, the semiconductor device further comprises a gate dielectric layer in the gate trench between the gate electrode and the semiconductor layer structure, and the semiconductor device is configured so that during on-state operation a peak electric field value in the gate dielectric layer will be located in a portion of the gate dielectric layer that is below the upper surface of the semiconductor layer structure.

Pursuant to additional embodiments of the present invention, semiconductor devices are provided that include a silicon carbide based semiconductor layer structure that comprises an active region. A gate trench is provided in an upper portion of the semiconductor layer structure, the gate trench having a first rounded lower corner and a second rounded lower corner. A gate electrode is provided in the gate trench, and a gate dielectric layer is provided in the gate trench between the gate electrode and the semiconductor layer structure. The semiconductor device is configured so that a peak electric field in the gate dielectric layer during on-state operation is below an upper surface of the semiconductor layer structure.

In some embodiments, an upper surface of the gate electrode is below the upper surface of the semiconductor layer structure. In some embodiments, an upper surface of the gate electrode is below a midpoint of an arc defined by the first rounded upper corner. In some embodiments, an upper surface of the gate electrode is below a location where the first rounded upper corner has a smallest instantaneous angle. In some embodiments, the upper surface of the gate electrode is at least 0.1 microns below the location where the first rounded upper corner has the smallest instantaneous angle.

In some embodiments, a radius of curvature of the first rounded lower corner exceeds a radius of curvature of the second rounded upper corner. In some embodiments, a radius of curvature of the first rounded lower corner is at least twice a radius of curvature of the first rounded upper corner.

In some embodiments, the semiconductor layer structure further comprises a termination region that surrounds the active region, and the portion of the semiconductor layer in the active region comprises a drift region having a first conductivity type, a plurality of well regions having a second conductivity type that is different from the first conductivity type, and a plurality of source regions having the first conductivity type, each source region in an upper portion of respective one of the well regions.

In some embodiments, the semiconductor device of claim 25, further comprises a plurality of additional gate trenches in the upper surface of the semiconductor layer structure and a plurality of additional gate electrodes in the respective plurality of additional gate trenches, where an upper surface of a portion of each additional gate electrode that is within the active region is below the upper surface of the semiconductor layer structure.

In some embodiments, the semiconductor device is a Metal Oxide Semiconductor Field Effect Transistor (“MOSFET”) or an insulated Gate Bipolar Transistor (“IGBT”).

Pursuant to still further embodiments of the present invention, methods of forming a semiconductor device are provided. Pursuant to these methods, a semiconductor layer structure is provided that comprises silicon carbide. A patterned etch mask is formed on the semiconductor layer structure. A preliminary gate trench is formed in an upper surface of the semiconductor layer structure so that the preliminary gate trench has rounded lower corners, where a degree of rounding of the rounded lower corners exceeds any amount of rounding of the upper corners.

In some embodiments, the method also comprises further rounding the lower corners of the preliminary gate trench and simultaneously rounding the upper corners of the preliminary gate trench to form a gate trench in the upper surface of the semiconductor layer structure.

In some embodiments, the method further comprises removing the etch mask after further rounding the lower corners of the preliminary gate trench and simultaneously rounding the upper corners of the preliminary gate trench to form the gate trench.

In some embodiments, the preliminary gate trench has sharp upper corners. In some embodiments, the gate trench has sharp upper corners. In other embodiments, the gate trench has rounded upper corners.

In some embodiments, forming the preliminary gate trench in the upper surface of the semiconductor layer structure comprises etching the semiconductor layer structure through openings in the patterned etch mask to form the preliminary gate trench.

In some embodiments, an etchant used to form the preliminary gate trench includes a combination of fluoride and chlorine gases.

In some embodiments, forming the preliminary gate trench in the upper surface of the semiconductor layer structure comprises etching the semiconductor layer structure through openings in the patterned etch mask to form a trench in the semiconductor layer structure that has sharp lower and upper corners and then performing an etching step to remove the patterned etch mask, where the etching step rounds at least the lower corners of the trench to form the preliminary gate trench.

In some embodiments, the method further comprises performing an anneal in a hydrogen-containing atmosphere at a temperature of at least 1200° C. to further round the lower corners of the preliminary gate trench and to simultaneously round the upper corners of the preliminary gate trench to form a gate trench in the upper surface of the semiconductor layer structure.

In some embodiments, the method further comprises performing an anneal in an oxygen-containing atmosphere at a temperature of at least 1200° C. and then removing oxidized portions of the semiconductor layer structure to convert the preliminary gate trench into a gate trench having more rounded lower corners than the preliminary gate trench and having more rounded upper corners than the preliminary gate trench.

In some embodiments, the method further comprises forming a gate electrode in the gate trench, wherein an upper surface of the gate electrode is below the upper surface of the semiconductor layer structure.

In some embodiments, the method further comprises forming a gate electrode in the gate trench, wherein the upper surface of the gate electrode is below a midpoint of the arcs defined by the respective rounded upper corners.

In some embodiments, the method further comprises forming a gate electrode in the gate trench, wherein the upper surface of the gate electrode is below locations where the rounded upper corners have their respective smallest instantaneous angles.

In some embodiments, the upper surface of the gate electrode is at least 0.1 microns below the locations where the rounded upper corners have their smallest instantaneous angles.

### BRIEF DESCRIPTION OF DRAWINGS

FIG. 1 is a semi-log graph illustrating the relationship between the lifetime of the gate oxide layer as a function of applied electric field strength.

FIG. 2A is a schematic top view of a conventional trench gate silicon carbide power MOSFET.

FIG. 2B is a schematic top view of the conventional trench gate silicon carbide power MOSFET of FIG. 2A with various of the upper metal and dielectric layers removed.

FIG. 2C is a schematic cross-sectional view of two unit cells of the conventional trench gate silicon carbide power MOSFET of FIGS. 2A-2B.

FIG. 2D is an enlarged view of a portion of FIG. 2C.

FIG. 3A is a schematic cross-sectional view of a unit cell of a trench gate silicon carbide power MOSFET that illustrates a problem that may arise if the upper corners of the gate trenches are rounded.

FIG. 3B is a schematic cross-sectional view of a unit cell of a trench gate silicon carbide power MOSFET that illustrates how the problem shown in FIG. 3A may be avoided by not rounding the upper corners of the gate trenches.

FIG. 4A is a schematic cross-sectional view of two unit cells of a trench gate silicon carbide power MOSFET according to embodiments of the present invention.

FIG. 4B is an enlarged view of a portion of FIG. 4A.

FIG. 4C is an enlarged view of a portion of a unit cell of a modified version of the silicon carbide power MOSFET of FIGS. 4A-4B where the upper corners of the gate trenches are not rounded.

FIGS. 5A-5F illustrate a method of forming the trench gate silicon carbide power MOSFET of FIGS. 2A-2C.

FIG. 6 is a flow chart illustrating a method of fabricating a trench gate silicon carbide power MOSFET according to embodiments of the present invention.

FIGS. 7A and 7B are schematic cross-sectional views that illustrate how the lower and upper corners of the gate trenches of a silicon carbide power MOSFET according to embodiments of the present invention may be rounded during the processing step to use the gate trench etching mask.

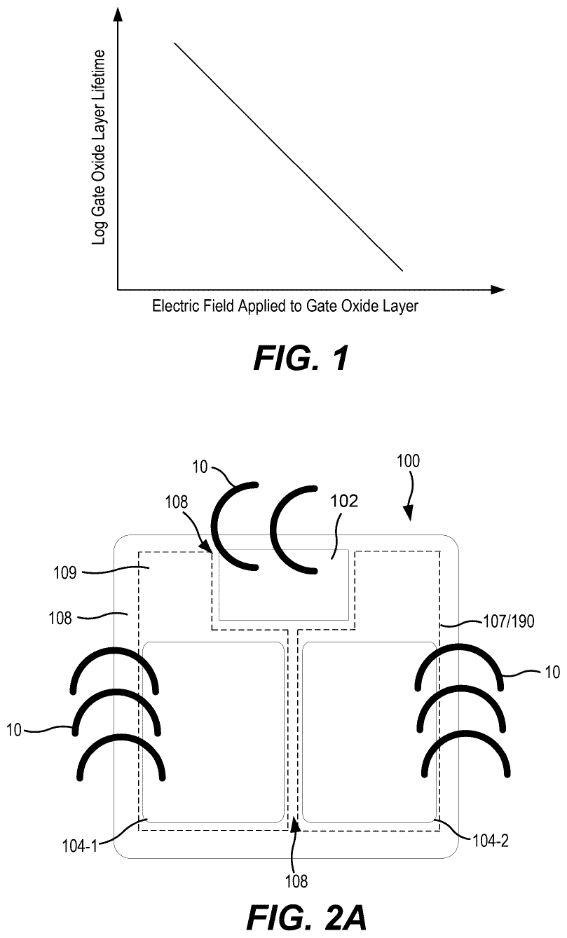

In the drawings and description below, two part reference numerals may be used that include a hyphen with respect to elements that have multiple instances. The full two-part reference numeral may be used to refer to specific ones on the elements designated by the reference numeral, while the first part of the two-part reference numeral may be used to refer to the elements designated by the reference numeral collectively.

### DETAILED DESCRIPTION

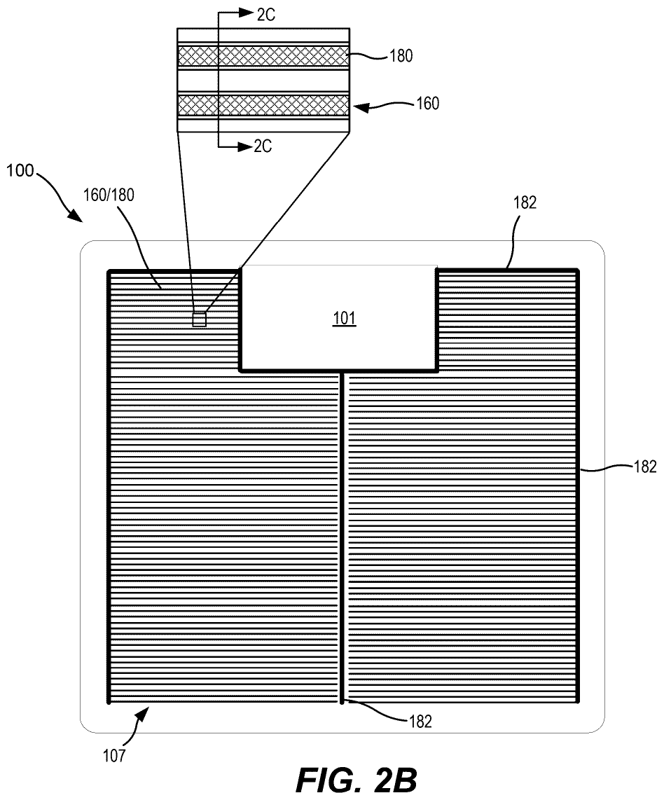

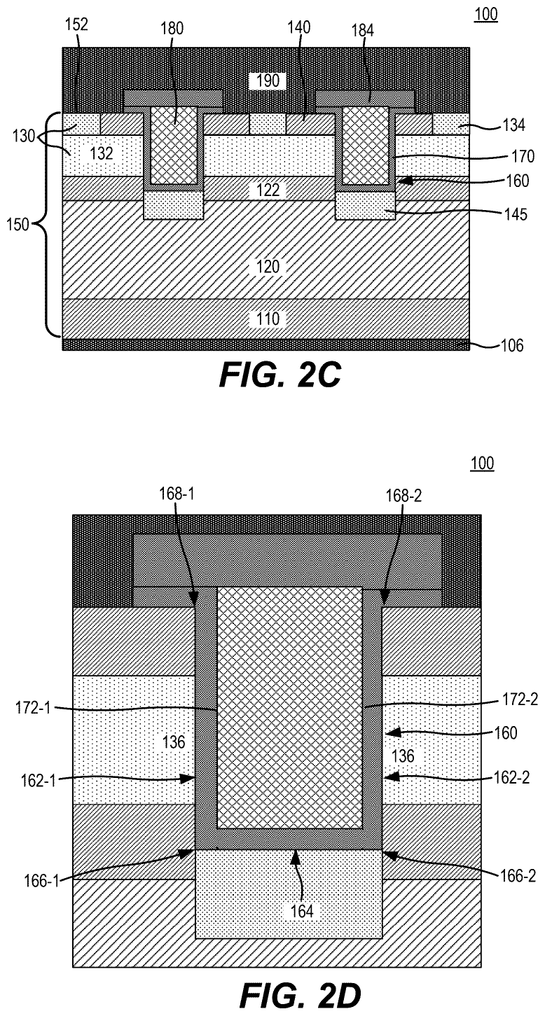

FIG. 2A is a schematic top view of a conventional trench gate silicon carbide power MOSFET 100. FIG. 2B is a schematic plan view of the conventional power MOSFET 100 with various top-side metal and dielectric layers thereof omitted to show the gate fingers and gate buses. It will be appreciated that the thicknesses of various of the layers, patterns and regions in FIGS. 2A-2B are not necessarily drawn to scale. The same is true with respect to the other figures included in this application.

The conventional power MOSFET 100 includes a semiconductor layer structure 150 (see FIG. 2C below) that comprises one or more semiconductor substrates and/or layers. At least one of the semiconductor layers in the semiconductor layer structure 150 may be a silicon carbide layer. Various metal and/or dielectric layers are formed on either side of the semiconductor layer structure 150 and embedded in the semiconductor layer structure 150.

As shown in FIG. 2A, the top-side metal layers include a gate bond pad 102 and one or more source bond pads 104-1, 104-2 that are formed on the upper side of the semiconductor layer structure 150. A metal drain pad 106 (not visible in FIG. 2A, but see FIG. 2C below)) is provided on the bottom side of the power MOSFET 100. The gate bond pad 102. the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad may likewise be a metal pad. A protective layer 109 such as a polyimide layer may cover the entire upper surface of power MOSFET 100 except for the gate and source pads 102, 104.

Still referring to FIG. 2A, the power MOSFET 100 includes a source contact 190 (indicated by the dashed boxes in FIG. 2A) that electrically connects certain regions of the semiconductor layer structure 150 to the source bond pads 104-1, 104-2. The source bond pads 104-1, 104-2 may be portions of the source contact 190 that are exposed through openings in the protective layer 109 or may be a separate metal layer. The source contact 190 may generally overlie or correspond to an “active region” 107 of the power MOSFET where the unit cell transistors are located. An inactive region 108 of power MOSFET 100 surrounds the active region 107. The inactive region 108 may include a termination region that extends around the periphery of the device that includes guard rings, junction termination elements or other termination structures (not shown), a gate pad region that underlies the gate pad 102, and gate bus regions (discussed below).

Bond wires 10 are shown in FIG. 2A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 2B is another plan view of power MOSFET 100 with the gate and source bond pads 102, 104, the polymide layer 109, the source contact 190 and various intermetal dielectric layers removed to show the gate trenches 160 and gate electrodes 180 that are formed in the semiconductor layer structure 150. As shown in FIG. 2B, a field oxide layer 101 is formed on the semiconductor layer structure 150. The field oxide layer 101 may be a relatively thick oxide layer (e.g., ten to twenty times thicker than the gate oxide layers that are discussed below) and may be formed in the region where the gate bond pad 102 is formed so that the gate bond pad 102 vertically overlaps the field oxide layer 101. As used herein, two elements of a semiconductor device are considered to “vertically overlap” if an axis that is perpendicular to the major surfaces of a semiconductor layer structure of the semiconductor device intersects both elements. One or more gate buses 182 are provided that extend around the periphery of the active region 107. The field oxide layer 101 typically runs underneath each gate bus 182 as well as underlying the gate bond pad 102. The gate buses 182 are electrically connected to the gate bond pad 102, often through gate resistors (not shown). A plurality of gate trenches 160 are formed throughout the active region 107. A gate electrode 180 is formed in each gate trench 160. In the depicted MOSFET, the gate electrodes 180 extend horizontally across the semiconductor layer structure 150. In other cases, the gate electrodes 180 may extend vertically across the semiconductor layer structure 150, both horizontally-extending and vertically-extending gate electrodes 180 can be provided to form a grid-like gate electrode structure, or annular hexagonal or other-shaped gate electrodes 180 may be used. The gate electrodes 180 may be connected to the gate pad 102 through the gate buses 182. The gate electrodes 180 may comprise, for example, a doped polysilicon pattern. The gate buses 182 may comprise polysilicon and/or metal structures in example embodiments and typically are in the inactive region 108 of power MOSFET 100.

FIG. 2C is a schematic cross-sectional view taken along line 2C-2C of FIG. 2B that illustrates two unit cells of the conventional trench gate silicon carbide power MOSFET 100. FIG. 2D is an enlarged view of a portion of the power MOSFET 100 of FIG. 2C.

As shown in FIG. 2C, the power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). A lightly-doped n-type (n-) silicon carbide drift layer 120 is provided on an upper surface of the substrate 110. Typically, the drift layer 120 is formed via an epitaxial growth process and is doped during growth. In some cases, an upper portion of the n-type drift region 120 may comprise an n-type current spreading layer 122 that is more heavily doped than the lower portion of the n-type drift region 120. The current spreading layer 122 may be doped during epitaxial growth and/or via ion implantation.

P-type silicon carbide well regions 130 are provided on the upper surface of the n-type drift region 120 (or on the n-type current spreading layer 122, if provided). The p-type silicon carbide well regions 130 may be formed by implanting p-type dopants into some or all of the upper portion of the n-type silicon carbide drift layer 120. Each p-type silicon carbide well region 130 may have an inverted “T” shape. The lower portion 132 of each p-type silicon carbide well region 130 may be a moderately doped p-type, while the upper portion 134 of each p-type silicon carbide well region 130 may be heavily doped p-type (or at least more heavily doped than the lower portion 132).

Heavily-doped (n+) n-type silicon carbide source regions 140 may be formed in upper portions of the p-type silicon carbide well regions 130. The n-type silicon carbide source regions 140 may be formed by ion implantation. The upper portion 134 of each p-type silicon carbide well region 130 is positioned between adjacent n-type silicon carbide source regions 140. While the upper portion 134 of each p-type silicon carbide well region 130 is positioned between the n-type silicon carbide source regions 140 that are adjacent different gate trenches 160 (which are discussed below) in the device depicted in FIG. 2C, it will be appreciated that in other cases the upper portions 134 of each p-type silicon carbide well region 130 may be positioned between adjacent n-type silicon carbide source regions 140 that are adjacent the same gate trench 160.

As is further shown in FIG. 2C. p-type silicon carbide trench shielding regions 145 are provided in the drift region 120. The p-type trench shielding regions 145 may be electrically connected to the p-type silicon carbide well regions 130 through electrical connections not shown in the cross-section of FIG. 2C.

The n-type silicon carbide substrate 110, the n-type silicon carbide drift layer 120 (including any current spreading layer 122), the p-type silicon carbide well regions 130, the n-type silicon carbide source regions 140 and the p-type silicon carbide trench shielding regions 145 may together comprise a semiconductor layer structure 150 of the power MOSFET 100.

Referring to FIGS. 2B and 2C, a plurality of gate trenches 160 are formed in the upper portion of the semiconductor layer structure 150. While only two gate trenches 160 are shown in the cross-section of FIG. 2C, it will be appreciated from FIG. 2B that the MOSFET may include a large number of gate trenches 160. Each gate trench 160 may extend along a longitudinal axis through the semiconductor layer structure 150, and the gate trenches 160 may extend in parallel to each other as shown best in FIG. 2B. Referring to the enlarged view of FIG. 2D, each gate trench 160 has first and second sidewalls 162-1, 162-2 and a bottom surface 164. In addition, each gate trench 160 has first and second lower corners 166-1, 166-2 and first and second upper corners 168-1, 168-2. It will be appreciated that the gate trenches 160 extend into the page in the view of FIG. 2C, and hence the lower corners 166 of the gate trench 160 refer to the locations where the first and second sidewalls 162-1, 162-2 of the gate trench 160 meet or intersect the bottom surface 164 of the gate trench 160. The upper corners 168 of a gate trench 160 refer to the locations where the first and second sidewalls 162-1, 162-2 of the gate trench 160 meet or intersect the upper surface 152 of the semiconductor layer structure 150. Both the lower corners 166 and the upper corners 168 of each gate trench 160 extend longitudinally and hence refer to two-dimensional corners as opposed to three-dimensional corners that are present, for example in a cube.

A gate oxide layer 170 is provided in each gate trench 160 to cover the sidewalls 162 and bottom surface 164 of the gate trench 160. Each gate oxide layer 170 may extend onto the upper surface of the semiconductor layer structure 150. Each gate oxide layer 170 may comprise, for example, a silicon oxide (SiO₂) pattern. The gate oxide layers 170 may or may not be connected to each other outside the view of FIG. 2C. The gate oxide layers 170 may be formed generally conformally within the respective gate trenches 160. As such, each gate oxide layer 170 has first and second sidewalls 172-1, 172-2 and a bottom surface.

A gate electrode 180 is formed in each gate trench 170 on the gate oxide layer 170. The gate electrodes 180 may comprise conductive material such as polysilicon and/or a metal. The gate oxide layer 170 may insulate the gate electrode 180 from the semiconductor layer structure 150, thereby preventing the gate electrodes 180 from short circuiting to the semiconductor layer structure 150. Each gate electrode 180 may connect to one of the gate buses 182 outside the active region 107.

Intermetal dielectric layers 184 are formed that cover each gate electrode 180. A source contact 190 is formed on the upper surface of the semiconductor layer structure 150 and on the intermetal dielectric layers 184. The intermetal dielectric layers 184 insulate the source contact 190 from the gate electrodes 180. The source contact 190 directly contacts the source regions 140 and the upper portions 134 of each p-type silicon carbide well region 130.

The drift layer 120 and the substrate 110 together act as a common drain region for the power MOSFET 100. The drain pad 106 is formed on the substrate 110 opposite the drift region 120.

The power MOSFET 100 may be turned on by applying a gate bias voltage that is above a threshold level to the gate pad 102. The gate bias voltage is transferred to the gate electrodes 180 via the gate buses 182 and creates conductive n-type inversion layers in the portion of each p-type silicon carbide well region 130 that are adjacent the gate trenches 160. These regions of the p-type silicon carbide well region 130 are referred to herein as channel regions 136 as current flows from the source regions 140 to the drift region 120 through these regions during on-state operation.

As discussed above, one common failure mechanism in power semiconductor devices such as power MOSFETs is device failure due to breakdown of the gate oxide layer. Since the lifetime (i.e., time until breakdown) of a gate oxide layer is a function of the intensity of the electric field in the gate oxide layer during device operation, one way to reduce the instances of device failure is to design the device to have reduced peak electric field values in the gate oxide layer.

The location where the electric field in the gate oxide layer will have its peak intensity differs depending upon the state of the power MOSFET 100. During on-state operation, the peak electric fields are formed in portions of the gate oxide layer 170 that are adjacent the gate electrodes 180, with the electric fields being the highest in the upper portions of the gate oxide layer 170. During reverse blocking operation, the electric field extends upwardly from the bottom of the MOSFET 100 and hence the strength of the electric field during reverse blocking operations is highest in the lower portion of the gate oxide layer 170.

The intensity of the electric field that is generated in the gate oxide layer 170 of the conventional power MOSFET 100 during on-state operation is not the same throughout the gate oxide layer 170. During on-state operation, a voltage is applied to the gate electrode 180 so that the sidewalls of the gate electrode 180 and the portions of the semiconductor layer structure 150 that form the sidewalls 162 of the gate trenches 160 effectively form the electrodes of a parallel plate capacitor, with the sidewalls 172 of the gate oxide layer 170 acting as the dielectric of these parallel plate capacitors. Consequently, during on-state operation, the electric field will have a generally constant value throughout the “parallel-plate” regions of the gate oxide layers 170. However, electric field crowding effects that concentrate the electrical field in the portions of the gate oxide layer 170 that extend around each upper corner 168 of the gate trenches 160 will occur that can significantly increase the electric field levels in the upper portions of each gate oxide layer 170. The sharper the corners of the gate trench 160, the greater the electric field crowding effects, and hence the higher the increase in the electric field values in the upper corners of the gate oxide layer 170. As shown in FIGS. 2C-2D, the lower corners 166 and the upper corners 168 of each gate trench 160 are typically “sharp” corners that have essentially no rounding. In this case, the peak electric field values in the upper corners of each gate oxide layer 170 may be 10%, 20%, 50%, 100% or even 200% greater than the peak electric field values in the parallel-plate regions of the gate oxide layers 170. Consequently, the upper corners of the gate oxide layer 170 are much more likely to experience breakdown as compared to the parallel-plate regions of the gate oxide layers 170.

Electric fields are also generated in the gate oxide layer 170 when power MOSFET 100 is in its reverse blocking or off-state. In the reverse blocking state, the electric field extends upwardly from the bottom of the MOSFET 100 and hence the strength of the electric field during reverse blocking operations is highest in lower portions of each gate oxide layer 170. The p-type silicon carbide trench shielding regions 145 act as a shield that reduces the electric field values, and hence the electric field tends to be highest in the lower corners of each gate oxide layer 170. Moreover, the above-described electric field crowding effects occur in the lower corners of each gate oxide layer 170 further increasing the intensity of the electric field in this portion of each gate oxide layer 170. This is particularly true if the lower corners 166 of each gate trench 160 are sharp corners.

One known technique for reducing the above-described electric field crowding effects is to round the lower and upper corners 166, 168 of each gate trench 160. Herein, a corner of a gate trench is considered to be a rounded corner if the radius of the rounded corner is greater than 0.01 microns (10 nm). Since the gate oxide layers 170 are formed conformally in the gate trenches 160, the rounding of the corners 166, 168 of the gate trenches 160 act to round the corresponding corners of the gate oxide layer 170. Generally speaking, the more the corners of the gate trenches 160 and gate oxide layers 170 are rounded the more the reduction in electric field crowding effects and hence the lower the peak electric field values in the lower and upper corners of the gate oxide layers 170. The lower and upper corners 166, 168 of each gate trench 160 may be rounded, for example, using a high temperature (e.g., greater than 1200° C.) hydrogen anneal.

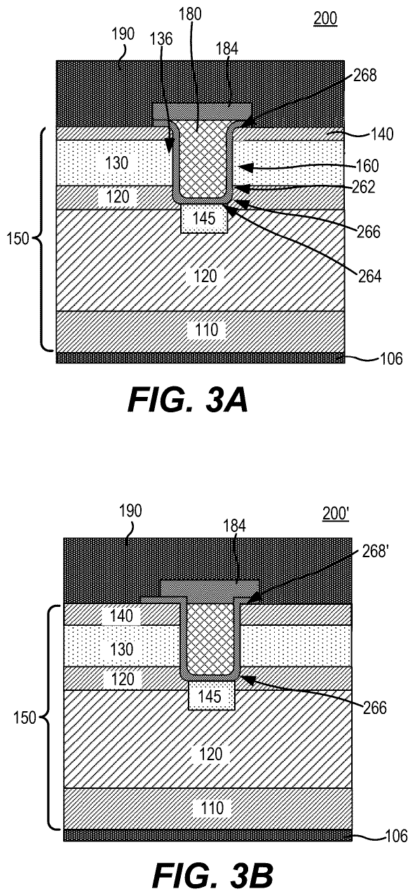

FIG. 3A is a schematic cross-sectional view of a unit cell of a trench gate silicon carbide power MOSFET 200 that illustrates a problem that may arise if the upper corners of the gate trenches are rounded. As shown in FIG. 3A, the power MOSFET 200 may be identical to the power MOSFET 100 of FIGS. 2A-2C except that the power MOSFET 200 has a gate trench 260 that has rounded lower and upper corners 266, 268.

Power MOSFET 200, like MOSFET 100 of FIGS. 2A-2C, includes a plurality of p-type trench shielding regions 145 that are formed underneath the respective gate trenches 260. Typically, the p-type trench shielding regions 145 are formed by ion implantation, and may be formed either before or after the gate trenches 260 are formed in the upper portion of the semiconductor layer structure 150. Unfortunately, issues may arise with either formation process for the p-type trench shielding regions 145.

If the p-type trench shielding regions 145 are formed after the gate trenches 260 are formed, the p-type trench shielding regions 145 may be formed using a relatively low energy ion implantation process, as the p-type dopant ions are implanted directly into the portion of the semiconductor layer structure 150 underneath each gate trench 260. The use of such a lower energy ion implantation process may be preferred because it causes less damage to the lattice structure of the silicon carbide semiconductor layer structure 150. However, when the p-type dopant ions are implanted into the bottoms 264 of the gate trenches 260, the p-type dopant ions also will implant into the sidewalls 262 of the gate trenches 260, both because each sidewall 262 may be inclined a slight amount outwardly due to the etching processes used to form the gate trenches 260, and because some of the p-type dopant ions will reflect off the bottom surfaces 264 of the gate trenches 260 and implant directly into the sidewalls 262 thereof. The implantation of p-type dopants into the sidewalls 262 can be problematic because the implanted p-type dopants can (1) change the doping concentration of the p-type channel regions 136 from a desired and/or ideal doping concentration and/or (2) change the doping concentration of the portion of the drift region 120 that is below each channel region 136, thereby increasing the on-state resistance of the MOSFET 200. Moreover, in some cases, the p-type ions that are implanted into the sidewalls 262 of the gate trenches 260 can change the conductivity type of the portions of the drift region 120 that are below each channel region 136 from n-type to p-type. If this occurs, the MOSFET 200 may become inoperable because the lower portion of the gate electrode 180 will not overlap an n-type region in the semiconductor layer structure 150. It is possible to remove the implanted p-type ions after the p-type trench shielding regions 145 are formed by etching the sidewalls 262 of the gate trenches 260 to remove the portions having p-type ions implanted therein (e.g., an oxidation process may be performed and then an etch may be performed that removes the silicon oxide formed by the oxidation process). However, the extra etching process (1) increases fabrication costs, (2) increases the widths of the gate trenches 260 (reducing integration density) and (3) may make the gate trenches 260 wider than the p-type trench shielding regions 145, which reduces the effectiveness of the p-type trench shielding regions 145.

Because of the above-described disadvantages, the p-type trench shielding regions 145 may alternatively be formed before the gate trenches 260 are formed using a relatively high energy deep ion implantation process that implants the p-type dopant ions through the n-type source regions 140 and the p-type well regions 130 into the drift region 120 underneath the regions where the gate trenches 260 will later be formed. Using such a deep ion implantation process may reduce the extent to which p-type dopant ions are implanted into the sidewalls 262 of the later formed gate trenches 260 (particularly if channeled ion implants are used) and may allow the p-type shielding regions 145 to be formed to be as wide as the respective gate trenches 260. However, the high energy ion implantation process may result in increased damage to the silicon carbide lattice, which may negatively impact the electrical performance of the MOSFET 200. In order to reduce the energy of the ion implant process, the depth of the source regions 140 into the semiconductor layer structure 150 may be reduced so that the gate trenches 260, and hence the p-type trench shielding regions 145, do not need to extend as far into the semiconductor layer structure 150. The MOSFET 200 of FIG. 3A has source regions with reduced depths.

As discussed above, a technique that can be used to reduce the electric field levels in the upper corners of the gate oxide layer is to round the upper corners of the gate trenches, as the more rounding that is provided the less the electric field crowding effects. However, as shown in FIG. 3A, if the upper corners 268 of the gate trenches 260 are rounded heavily, the amount of overlap between the gate electrode 180 and the source region 140 may be reduced significantly. This is particularly true if the source regions 140 are formed to a relatively small depth into the semiconductor layer structure 150. In a MOSFET having the design of FIG. 3A, process variations may result in the gate electrode 180 not overlapping a straight portion of the sidewall of the source regions 140, which may reduce the performance of power MOSFET 200 or even result in an inoperable device.

FIG. 3B is a schematic cross-sectional view of two unit cells of a trench gate silicon carbide MOSFET 200′ that illustrates how the problem shown in FIG. 3A may be avoided by not rounding the upper corners 268 of the gate trenches 260. As shown in FIG. 3B. if the upper corners 268′ of the gate trenches 260 are not rounded, then it may be relatively easy to ensure that the gate electrode 180 overlaps portions of the source regions 140 that have straight sidewalls. However, the sharp upper corners 268′ of the gate trenches 260 will lead to electric field crowding effects, as discussed above, which may make lead to premature breakdown in the upper corners of the gate oxide layers 170. Moreover, if the upper corners 268′ of the gate trenches 260 are not rounded, the amount of rounding of the bottom corners 266 of the gate trenches 260 may be reduced or even eliminated. This can make the lower corners of the gate oxide layer 170 more susceptible to breakdown, particularly during reverse blocking operation. Thus, the design of a gate trench power MOSFET involves a variety of tradeoffs, each of which has different positive and negative impacts on device performance and/or device fabrication cost.

Pursuant to embodiments of the present invention, gate trench power semiconductor devices (e.g., power MOSFETs) are provided that may have more robust gate oxide layers, particularly during on-state operation. In some embodiments, the gate trench power semiconductor devices may have gate trenches that have both rounded lower and upper corners where the upper corners are rounded less than the lower corners. This design may ensure that the gate electrodes properly overlap the source regions while also reducing electric field crowding effects during both on-state and reverse bias operation. In addition, the gate electrodes of the gate trench power semiconductor devices according to embodiments of the present invention may be recessed so that they are coplanar with or below an upper surface of the semiconductor layer structure. In some embodiments, the upper surfaces of the gate electrodes may be recessed to be below the rounded upper corners of the gate trenches. As such, the locations in the gate oxide layers where the peak electric field levels are experienced during on-state operation may be in the “parallel plate” regions of the gate oxide layers, thereby avoiding the electric field crowding effects that can increase the peak electric field values in the gate oxide layers.

According to some embodiments of the present invention, semiconductor devices are provided that comprise a silicon carbide based semiconductor layer structure that has an active region. A gate trench is provided in an upper portion of the semiconductor layer structure, the gate trench having a first rounded lower corner and a second rounded lower corner. A gate electrode is provided in the gate trench. Within the active region, an upper surface of the gate electrode is below or coplanar with an upper surface of the semiconductor layer structure. The upper corners of the gate trench may be sharp or rounded corners. A radius of curvature (if any) of the upper corners of the gate trench may be less than a radius of curvature of the lower corners of the gate trench. The upper surface of the gate electrode may be recessed, for example, below a location where the upper corners of the gate trench have their smallest instantaneous angles. In example embodiments, the upper surface of the gate electrode may be recessed, for example, 10 nm, 20 nm, 50 nm 100 nm or 200 nm below the location where the upper corners of the gate trench have their smallest instantaneous angles.

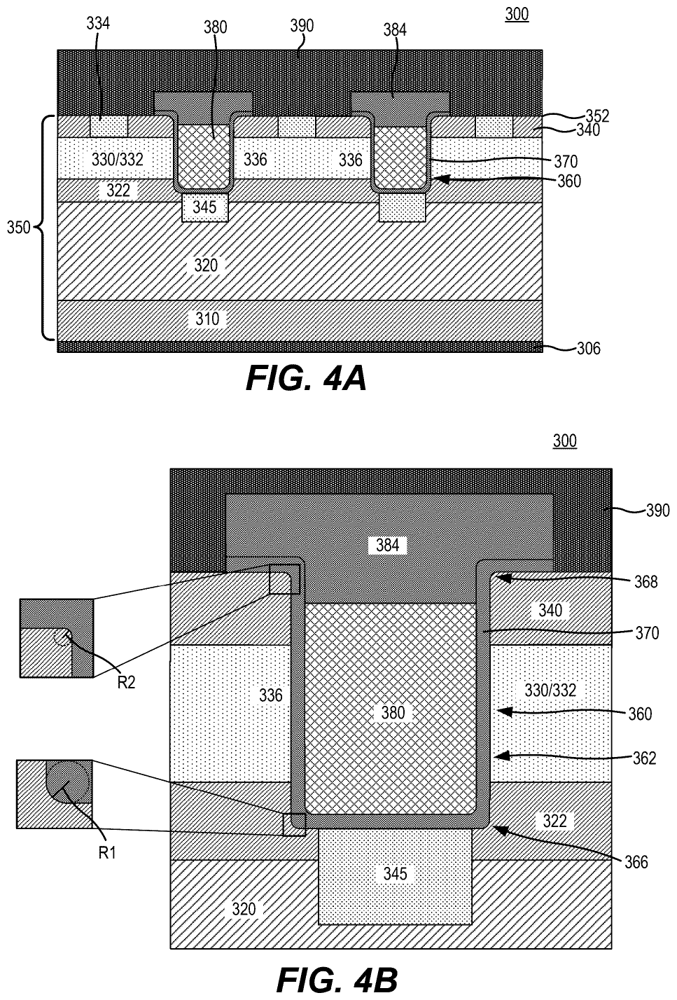

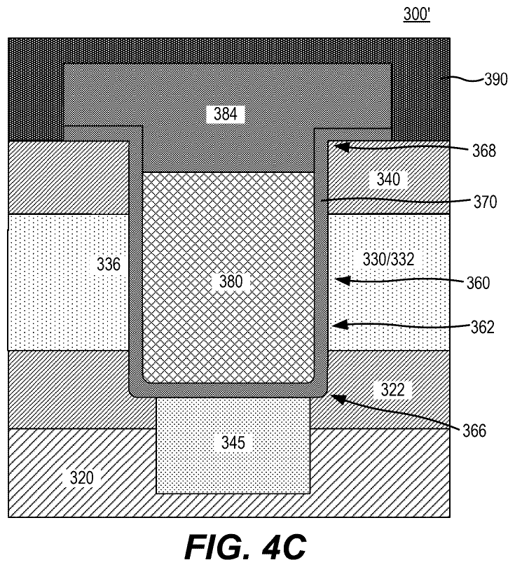

Semiconductor devices according to embodiments of the present invention will now be described in greater detail with reference to FIGS. 4A-6.

FIG. 4A is a schematic cross-sectional view of two unit cells of a trench gate silicon carbide MOSFET 300 according to embodiments of the present invention. In plan view (i.e., when viewed from above), the MOSFET 300 may appear identical to the gate trench MOSFET 100 illustrated in FIGS. 2A-2B, and the cross-section of FIG. 4A corresponds to the cross-section taken along lines 2C-2C of FIG. 2B. FIG. 4B is an enlarged view of one of the gate electrodes of FIG. 4A.

As shown in FIGS. 4A-4B, the power MOSFET 300 includes an n-type silicon carbide semiconductor substrate 310. The substrate 310 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the substrate may have a doping concentration of, for example, between 1×10¹⁸ atoms/cm³ and 1×10²¹ atoms/cm³, although other doping concentrations may be used. The substrate 310 may be relatively thick in some embodiments (e.g., 20-100 microns or more). It should be noted that while the substrate 310 is are depicted as a relatively thin layer, this is done to allow enlarging the thickness of other layers and regions in FIGS. 4A-4B, and it will be appreciated that the substrate 310 will typically be much thicker than shown. The thickness of various other layers of power MOSFET 300 likewise may not be shown to scale in order to allow other portions of the devices to be enlarged in the figures.

A lightly-doped n-type (n-) silicon carbide drift region 320 (which also may be referred to herein as a drift layer 320) is provided on an upper surface of the substrate 310. The n-type drift region 320 may be formed, for example, by epitaxial growth on the substrate 310. The n-type drift region 320 may have, for example, a doping concentration of 5×10¹⁵ to 5×10¹⁷ dopants/cm³. The n-type drift region 320 may be a thick region, having a vertical height above the substrate 310 of, for example, 3-50 microns, and can be doped during growth. In some embodiments, an upper portion of the n-type drift region 320 may comprise an n-type current spreading layer 322 that is more heavily doped than the lower portion of the n-type drift region 320. If provided, the n-type current spreading layer 322 may have an n-type dopant concentration of, for example, 5×10¹⁶ to 1×10¹⁸. Herein, the n-type current spreading layer 322, if provided, is considered to be part of the drift region 320 and generally will not be referred to separately. The n-type current spreading layer 322, if provided, may be doped during epitaxial growth or via a later ion implantation step.

Still referring to FIG. 4A, a moderately-doped (p) p-type silicon carbide well layer is formed on the upper surface of the n-type drift region 320 or in an upper portion of the n-type drift region 320. The moderately-doped (p) p-type silicon carbide well layer may be formed cither by epitaxial growth or by implanting p-type dopant ions into the upper portion of the n-type drift region 320 to convert the upper portion of the n-type drift layer into the p-type silicon carbide well layer. When formed by ion implantation, the entirety of the upper portion of the n-type drift region 320 may be converted into a p-type silicon carbide well layer. The upper portion of the p-type silicon carbide well layer may be more heavily doped with p-type dopants than the lower portion thereof, and source regions 340 may be formed in the upper portion of the p-type silicon carbide well layer. Consequently, as shown in FIG. 4A, a plurality of p-type silicon carbide well regions 330 are formed in the upper portion of the n-type silicon carbide drift region 320 that each have an inverted “T” shape. The lower portion 332 of each p-type silicon carbide well region 330 may be a moderately doped p-type, while the upper portion 334 of each p-type silicon carbide well region 330 may be heavily doped p-type (or at least more heavily doped than the lower portion 332). In example embodiments, the lower portion 332 of each moderately-doped p-type well region 330 may have a p-type dopant concentration of, for example, 5×10¹⁶ to 1×10¹⁸. The moderately-doped p-type well regions 330 may have graded doping profiles in some embodiments.

Heavily-doped (n⁺) n-type silicon carbide source regions 340 are formed in upper portions of the p-type silicon carbide well layer to define the p-type silicon carbide well regions 330. The heavily-doped n-type silicon carbide source regions 340 are typically formed via ion implantation. When formed by ion implantation, selected upper portions of the p-type silicon carbide well layer are converted into the heavily-doped (n⁺) silicon carbide source regions 340. Each heavily-doped n-type silicon carbide source region 340 may have a doping concentration, for example, of between 1×10¹⁹ atoms/cm³ and 5×10²¹ atoms/cm³. The n-type dopants used to form the heavily-doped (n⁺) silicon carbide source regions 340 may be selectively implanted into the p-type silicon carbide well layer so that the upper portions 334 of the p-type silicon carbide well regions 330 are positioned between adjacent ones of the n-type silicon carbide source regions 340.

As is further shown in FIGS. 4A-4B. p-type silicon carbide trench shielding regions 345 are provided in the n-type silicon carbide drift region 320. The p-type trench shielding regions 345 may be electrically connected to the p-type silicon carbide well regions 330 through p-type silicon carbide trench shield connection patterns that are not shown in the cross-sections of FIGS. 4A-4B. The p-type trench shielding regions 345 may be moderately or heavily doped (p⁺) silicon carbide regions. For example, each p-type trench shielding region 345 may have a doping concentration between about 1×10¹⁷ and 1×10²¹. In other embodiments, each p-type trench shielding region 345 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In example embodiments, each p-type trench shielding region 345 may extend to a depth of between 0.5 and 3.0 microns from the upper surface of the semiconductor layer structure 350. In other embodiments, the depth of each p-type trench shielding region 345 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the p-type trench shielding regions 345. The p-type trench shielding regions 345 may act to reduce the electric field levels that form in gate oxide layers (discussed below) during device operation, as will be discussed in greater detail below.

U.S. Pat. Nos. 9,887,287 and 11,610,991 each illustrate designs for p-type silicon carbide trench shield connection patterns that can be used to electrically connect the p-type trench shielding regions 345 to the p-type silicon carbide well regions 330. Any of the p-type silicon carbide trench shield connection patterns disclosed in these patent publications (each of which is incorporated herein by reference) can be used to electrically connect the p-type trench shielding regions 345 to the p-type silicon carbide well regions 330. Additionally or alternatively, the p-type trench shielding regions 345 may be directly connected to the source contact 390 through p-type silicon carbide trench shield connection patterns that, for example, are formed in the gate trenches, as shown in U.S. Patent Publication No. 2022/0130998, the entire content of which is also incorporated herein by reference in its entirety.

The substrate 310, the n-type silicon carbide drift region 320, the p-type silicon carbide well regions 330, the n-type silicon carbide source regions 340, the p-type silicon carbide trench shielding regions 345 and the p-type silicon carbide trench shield connection patterns (not shown) may together comprise a semiconductor layer structure 350 of the power MOSFET 300.

A plurality of gate trenches 360 are formed in the upper portion of the semiconductor layer structure 350. While only two gate trenches 360 are shown in the cross-section of FIG. 4A, it will be appreciated that the MOSFET 300 may include a large number of gate trenches 360. The gate trenches 360 may be formed via an etching process. Each gate trench 360 may extend along a longitudinal axis through the semiconductor layer structure 350, and the gate trenches 360 may extend in parallel to each other (see FIG. 2B). Each gate trench 360 extends into an upper surface of the n-type drift region 320. Each gate trench 360 has first and second sidewalls 362-1, 362-2 and a bottom surface 364. In addition, each gate trench 360 has first and second lower corners 366-1, 366-2 and first and second upper corners 368-1, 368-2. Both the lower corners 366 and the upper corners 368 of each gate trench 360 extend longitudinally and hence are two-dimensional corners as opposed to three-dimensional corners that are present, for example in a cube.

A gate oxide layer 370 is formed in each gate trench 360 to cover the bottom surface 364 and sidewalls 362 of the gate trench 360. Each gate oxide layer 370 may extend onto the upper surface of the semiconductor layer structure 350. Each gate oxide layer 370 may comprise, for example, a silicon oxide (SiO₂) pattern. The gate oxide layers 370 may or may not be connected to each other. The gate oxide layers 370 may be formed generally conformally within the respective gate trenches 360 in some embodiments.

A gate electrode 380 is formed in each gate trench 360 on the gate oxide layer 370 opposite the semiconductor layer structure 350. The gate electrode 380 may include, for example, a silicide (e.g., NiSi, TiSi, WSi, CoSi), doped polycrystalline silicon (poly-Si), and/or a stable conductor. Other suitable materials for the gate electrode include various metals such as Ti, Ta or W or metal nitrides such as TiN, TaN or WN. The gate oxide layer 370 insulates the gate electrodes 380 from the semiconductor layer structure 350, thereby preventing the gate electrodes 380 from short circuiting to the semiconductor layer structure 350. Each gate electrode 380 may connect to one or more of the gate buses outside the active region 306.

Intermetal dielectric layers 384 are formed that cover each gate electrode 380. A source contact 390 (corresponding to source contact 190 of FIG. 2A) is formed on the upper surface of the semiconductor layer structure 350 and on the intermetal dielectric layers 384. The intermetal dielectric layers 384 insulate the source contact 390 from the gate electrodes 380. The source contact 390 directly contacts the source regions 340 and the upper portions 334 of each p-type silicon carbide well region 330.

The drift layer 320 and the substrate 310 together act as a common drain region for the power MOSFET 300. A drain pad 306 (corresponding to drain pad 106 of FIG. 2A) is formed on the substrate 310 opposite the drift region 320.

The power MOSFET 300 may be turned on by applying a gate bias voltage that is above a threshold level to a gate pad 102 (see gate pad 102 of FIG. 2A). The gate bias voltage is transferred to the gate electrodes 380 via gate buses and creates conductive n-type inversion layers in the channel regions 336 of each p-type silicon carbide well region 330 that are adjacent the gate trenches 360 so that current flows from the source regions 340 to the drift region 320 during on-state operation.

As will be discussed in detail below, the power semiconductor devices according to embodiments of the present invention may be designed so that the peak electric fields that are generated in the gate oxide layers during on-state operation will occur in or close to the “parallel plate” regions of the gate oxide layers and will not occur at the locations where the upper corners of the gate oxide layers have their maximum instantaneous angles. As a result, the peak electric field levels in the gate oxide layers during on-state operation will be reduced as compared to conventional power semiconductor devices, since the negative effects of electric field crowding during on-state operation may be reduced or even eliminated in the power semiconductor devices according to embodiments of the present invention. In addition, the power semiconductor devices according to embodiments of the present invention may have relatively shallow source regions while still guaranteeing that straight portions of the sidewalls of the source regions horizontally overlap the respective gate electrodes. As used herein, two elements of a semiconductor device are considered to “horizontally overlap” if an axis that is parallel to the major surfaces of a semiconductor layer structure of the semiconductor device intersects both elements. Consequently, the p-type trench shielding regions in the power semiconductor devices according to embodiments of the present invention may be formed prior to formation of the gate trenches without having to use excessively high ion implantation energies.

As will be explained in detail below, the power semiconductor devices according to embodiments of the present invention may achieve the above discussed performance improvements because the upper corners of the gate trenches may be rounded less than the lower corners of the gate trenches or not rounded at all. In addition, the portions of the gate electrodes in the active region may be recesses so that the upper surface of each gate electrode is below an upper surface of the semiconductor layer structure (note that outside the active region the gate electrodes may extend higher to contact the gate buses). As a result, the capacitors that form between the gate electrodes and the semiconductor layer structure will not extend as far upwardly, and hence will overlap less of the upper corners of the gate oxide layers or may even be designed to not overlap the upper corners of the gate oxide layers at all. As such, the intensity of the electric fields that form in the upper corners of the gate oxide layers may be significantly reduced, and the peak electric field levels may occur in the straight sidewall portions of the gate oxide layers.

Certain features of the power semiconductor devices according to embodiments of the present invention that provide these advantages can best be seen in the enlarged view of FIG. 4B. As shown in FIG. 4B, the lower trench corners 366 may be rounded corners that have a first radius of curvature R1 while the upper trench corners 368 may be rounded corners that have a second radius of curvature R2 that is smaller than the first radius of curvature R1. In some embodiments, R1 may be 25%, 50% or 75% greater than R2. In other embodiments, R1 may be twice, three times, four times or even five times greater than R2. Moreover, as shown in FIG. 4C, in other embodiments the upper corners 368 may not be rounded at all to provide a MOSFET 300′. Because the upper trench corners 368 are only rounded a relatively small amount, the power semiconductor devices according to embodiments of the present invention may have shallow source regions 340 (e.g., source regions 340 having depths into the semiconductor layer structure 350 of between 0.05 and 2.0 microns, between 0.1 and 1.0 microns, between 0.2 and 0.8 microns or between 0.3 and 0.5 microns) while still ensuring that the gate electrodes 380 will properly overlap the source regions 340. Moreover, since the amount of rounding of the lower trench corners 366 is made independent of the amount of rounding of the upper trench corners 368, the lower trench corners 366 may be rounded an amount that optimizes performance during reverse blocking operation. Typically, the lower trench corners 366 will be rounded at least 50% more than the upper trench corners 368 in order to reduce electric field crowding effects in the lower trench corners 366 during reverse blocking operation. In other embodiments, the lower trench corners 366 may be rounded at least 25% more, at least 75% more at least 100% more or at least 150% more than the upper trench corners 368.

The gate electrodes 380 are recessed so that they are coplanar with or (as shown in FIG. 4B) below, the upper surface 352 of the semiconductor layer structure 350. In the example embodiment shown in FIG. 4B, the gate electrodes 380 are recessed well below the upper surface 352 of the semiconductor layer structure 350 so that the gate electrodes 380 do not horizontally overlap the rounded upper corners 368 of the gate trenches 360. Since the electric fields generated in the gate oxide layers 370 during on-state operation are generated by the capacitor that forms between the gate electrodes 380 and the semiconductor layer structure 350, forming the gate electrodes 380 to not horizontally overlap the rounded upper corners 368 of the gate trenches 360 ensures that the electric fields that form in the upper corners of the gate oxide layers 370 have reduced values. If the upper surfaces of the gate electrodes 380 are sufficiently spaced apart from the upper corners of the gate oxide layers 370 (and hence from the rounded upper corners 368 of the gate trenches 360), then the peak electric fields during on-state operation may occur in portions of the gate oxide layers 370 that are between the lower and upper corners (these portions are referred to herein as the “straight sidewall” portions of the gate oxide layers 370). Since the straight sidewall portions of the gate oxide layers 370 are not subject to electric field crowding effects, this design may act to reduce the peak electric fields experienced by the gate oxide layers 370 during on-state operation, thereby extending the life of the gate oxide layers 370 so that the power semiconductor devices according to embodiments of the present invention exhibit improved reliability.

Referring again to FIGS. 4A and 4B, it can be seen that the MOSFET 300 includes a silicon carbide based semiconductor layer structure 350. A gate trench 360 is formed in an upper portion of the semiconductor layer structure 350, the gate trench 360 has a first rounded lower corner 366-1 and a second rounded lower corner 366-2. A gate electrode 380 is formed in the gate trench 360. Moreover, within an active region of the MOSFET 300, an upper surface of each gate electrode 380 is below or coplanar with an upper surface 352 of the semiconductor layer structure 350. The gate trench 360 may also have a first rounded upper corner 368-1 and a second rounded upper corner 368-2, although in other embodiments both upper corners 368 of the gate trench 360 may be sharp corners. If the upper corners 368 of the gate trench 360 are rounded, they may be rounded less than the lower corners 366 of the gate trench 360 (i.e., a radius of curvature of each rounded lower corner 366 exceeds a radius of curvature of each rounded upper corner 368). The MOSFET 300 may be configured so that a peak electric field in the gate dielectric layer 370 during on-state operation is below an upper surface of the semiconductor layer structure 350.

In example embodiments, the upper surface of each gate electrode 380 may be recessed below the upper surface 352 of the semiconductor layer structure 350 so that the upper surface of the gate electrode 380 is below a midpoint of an arc defined by the first rounded upper corner 368-1. In other embodiments, the upper surface of each gate electrode 380 may be recessed below the upper surface 352 of the semiconductor layer structure 350 so that the upper surface of the gate electrode 380 is below a location where the first rounded upper corner 368-1 has a smallest instantaneous angle, as this is the location which will be most impacted by electric field crowding effects. In some cases, the upper surface of each gate electrode 380 may be recessed at least 0.1 microns or at least 0.2 microns below a location where the first rounded upper corner 368-1 has its smallest instantaneous angle.

While the example embodiments of the present invention that are discussed herein discuss power semiconductor devices that include silicon dioxide gate oxide layers, it will be appreciated that embodiments of the present invention are not limited thereto. For example, in other embodiments, other gate oxide layers may be used (e.g., silicon oxynitride) or the gate oxide layers may be replaced with gate dielectric layers that comprise non-oxide dielectrics (e.g., silicon nitride). It will also be appreciated that the gate oxide layers (or other gate dielectric layers) may comprise multilayer structures in some embodiments.

It will also be appreciated that the semiconductor layer structure 350 shown in FIG. 4A is merely an example, and that semiconductor layer structures having other configurations may be used without deviating from the scope of the present invention. For example, the semiconductor layer structure 350 may include additional layers or regions such as, for example, additional p-type blocking regions that are positioned between adjacent gate electrodes 380. It will also be appreciated that the embodiments described herein may be utilized in any gate-controlled semiconductor devices that use a metal-oxide and/or metal-insulator interface, such as MISFETs, IGBT devices and gate-controlled thyristors, to name a few. Thus, it will be understood that the semiconductor layer structure 350 can take multiple other forms without deviating from the embodiments described herein

It will also be appreciated that the above description is of an n-type power semiconductor device (an n-type MOSFET). In p-type devices, the locations of the source and drain contacts may be reversed, and the conductivity types of the other n-and p-type regions may be swapped. All of the embodiments disclosed herein may be implemented either as n-type or as p-type devices.

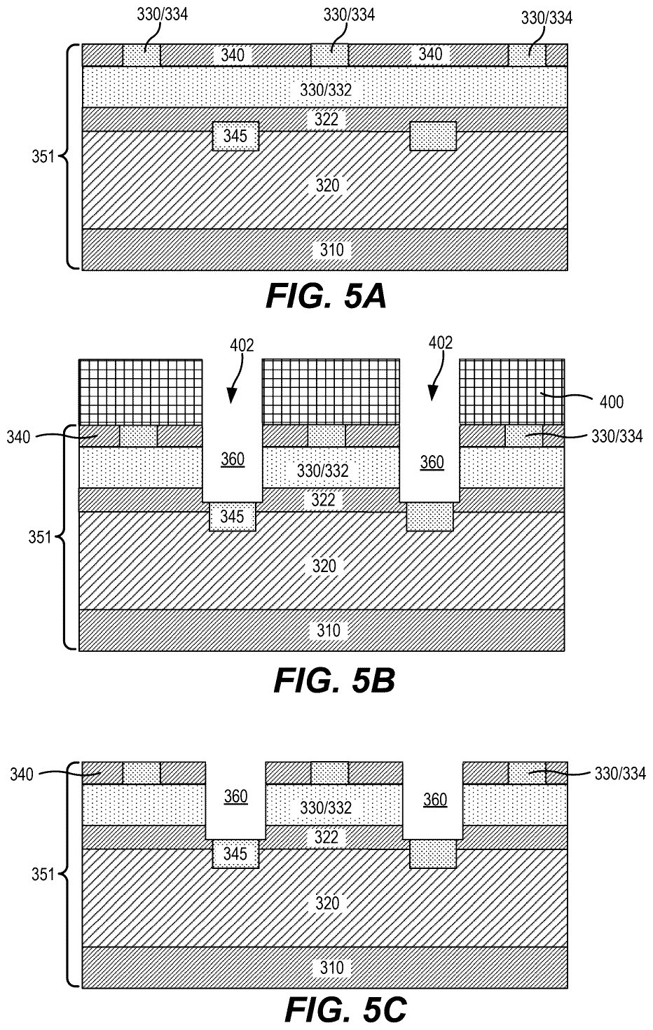

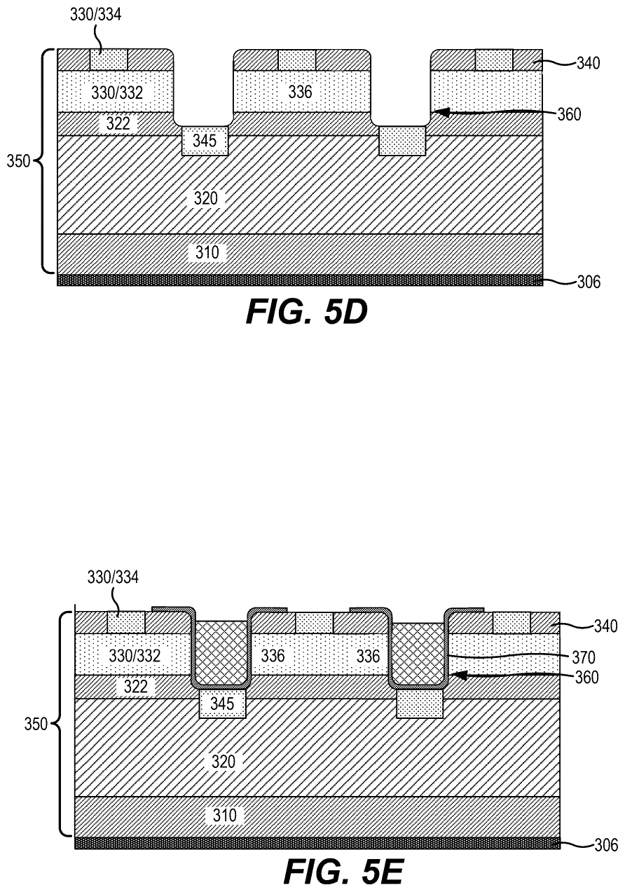

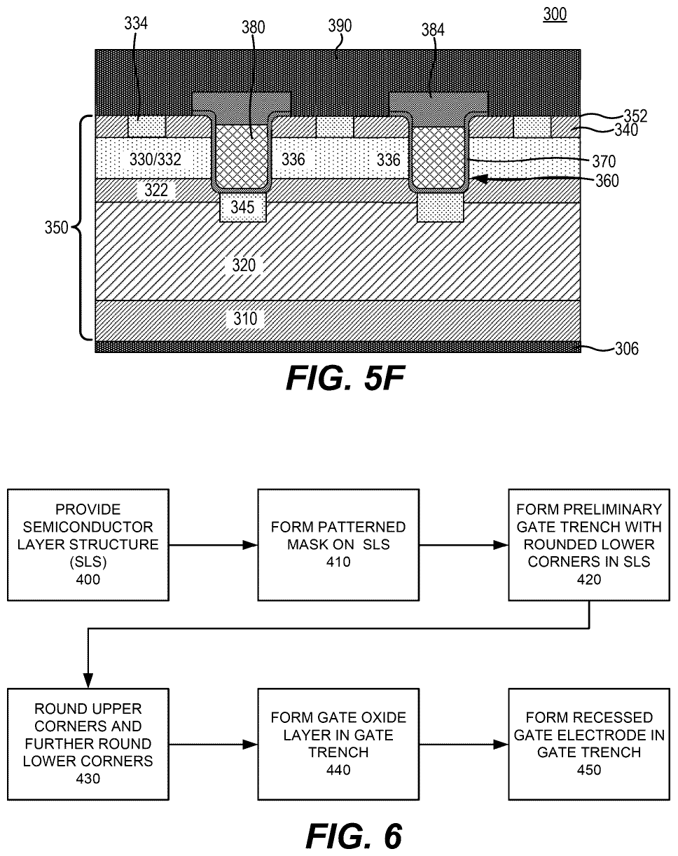

FIGS. 5A through 5F are schematic cross-sectional views illustrating process steps that may be used to fabricate the MOSFET 300 of FIGS. 4A-4B.

Referring to FIG. 5A, a preliminary semiconductor layer structure 351 may be formed. For example, a heavily-doped (n⁺) n-type silicon carbide substrate 310 is provided and a lightly-doped (n³¹ ) silicon carbide drift layer 320 is formed on the substrate 310 via epitaxial growth. An n-type silicon carbide current spreading layer 322 is formed in the upper portion of the drift layer 320 by increasing the n-type dopant concentration during the epitaxial growth process. The n-type silicon carbide current spreading layer 322 may extend to the upper surface of the preliminary semiconductor layer structure 351 or may be formed as a buried n-type silicon carbide current spreading layer 322 such that the n-type dopant concentration is reduced (or even substantially eliminated) in the uppermost portion of the drift layer 320 since this portion of the drift layer 320 will later be converted into a well layer and source regions.

Next, the above-discussed moderately-doped (p) p-type silicon carbide well layer is formed in the upper portion of the n-type drift region 320 by implanting p-type dopant ions into the upper portion of the n-type drift region 320 to convert the upper portion of the n- type drift layer into the p-type silicon carbide well layer. The entirety of the upper portion of the n-type drift region 320 may be converted into the p-type silicon carbide well layer or the p-type silicon carbide well layer may be formed as a buried layer that is formed above the n-type silicon carbide current spreading layer 322 but that does not extend to the surface of the preliminary semiconductor layer structure 351.

Next, the heavily-doped (n⁺) n-type silicon carbide source regions 340 are formed in the upper portion of the p-type silicon carbide well layer by ion implantation, which also acts to define the p-type silicon carbide well regions 330. In addition, the more heavily doped upper portions 334 of the p-type silicon carbide well regions 330 may be formed via a separate ion implantation step. Finally, p-type silicon carbide trench shielding regions 345 are formed in the n-type silicon carbide drift region 320 via ion implantation. It will be appreciated that the various ion implantation steps described above may be performed in any order and need not be formed in the order discussed above. It will also be appreciated that the p-type silicon carbide trench shielding regions 345 may be formed after the gate trenches 360 (FIG. 5B) are formed in other embodiments. It will also be appreciated that ion implantation masks (not shown) will be used in most or all of the ion implantation steps described above.

Referring to FIG. 5B, an etching mask 400 is blanket formed on the preliminary semiconductor layer structure 351 and then patterned to have openings 402 that expose regions where the gate trenches 360 are formed. The preliminary semiconductor layer structure 351 may then be etched to form the gate trenches 360 therein, which acts to convert the preliminary semiconductor layer structure 351 into the semiconductor layer structure 350. As shown in FIG. 5B, in some embodiments, both the lower corners 366 and the upper corners 368 of the gate trenches 360 will be sharp corners as etched. However, in some embodiments, the etch chemistry may be designed to round the lower corners 366 of the gate trenches 360 during the gate trench etch process. For example, the etchant used to etch the gate trenches 360 may include a combination of fluoride and chlorine gases, which can provide the desired rounding of the lower corners 366 of the gate trenches 360. In such embodiments, the etching mask 400 may protect the upper corners 368 of the gate trenches 360 so that they experience little or no rounding. Thus, while not shown in FIG. 5B, it will be appreciated that in some embodiments the lower corners 366 of the gate trenches 360 may be rounded as part of the gate trench eth processing step.

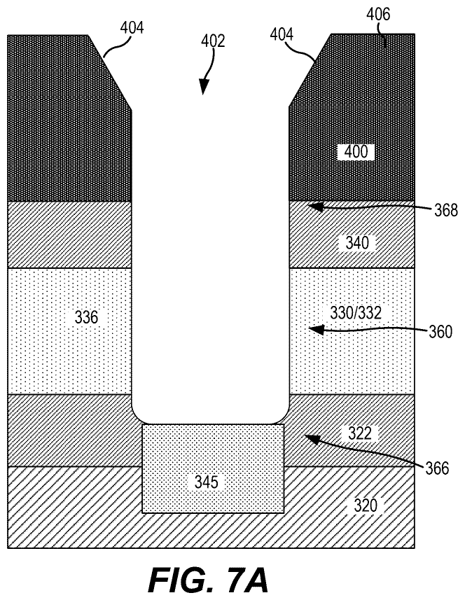

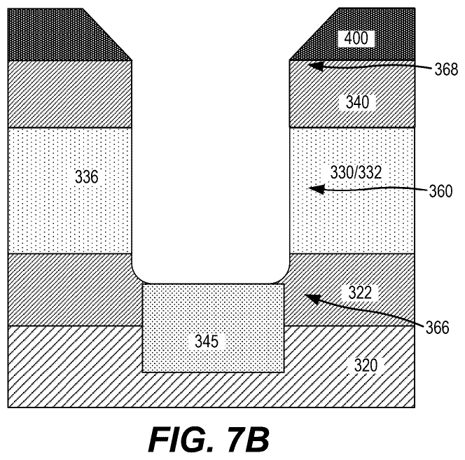

Referring to FIG. 5C, the patterned etching mask 400 may then be removed. As shown in FIG. 5C, in some embodiments, the etchant used to remove the patterned etching mask 400 may be highly selective with respect to silicon carbide so that little or no rounding of the lower and upper corners 366, 368 of the gate trenches 360 occurs when the patterned etching mask 400 is removed. However, it will be appreciated that in other embodiments, the etching step used to remove the patterned etching mask 400 may be used to further round the lower corners 366 of the gate trenches 360 and, in some cases, may also be used to round the upper corners 368 of the gate trenches 360. In particular, referring to FIG. 7A, it can be seen that depending upon the composition of the patterned etching mask 400 and the etchant used to etch the gate trenches 360, the upper corners 404 of the patterned etching mask 400 may be rounded or beveled during the gate trench etch. As shown, due to this rounding, the height of the patterned etching mask 400 adjacent each opening 402 may be significantly less than the height of the patterned etching mask 400 in central regions 406 that are between the openings 402. Referring to FIG. 7B, at the point where the patterned etching mask 402 is fully removed from each upper corner 368 of the gate trenches 360 a substantial amount of the patterned etching mask 402 will still remain on regions of the upper surface of the semiconductor layer structure 350 that are about midway between adjacent gate trenches 360. As the etchant acts to etch away the remaining portions of the patterned etching mask 400 it will also act to etch both the lower and upper corners 366, 368 of the gate trenches 360 to arrive at the gate trench 360 shown in FIG. 4B. Thus, in some cases the step of removing the patterned etching mask 400 may also be used to further round the lower corners 366 of the gate trenches 360 and to provide a desired degree of rounding to the upper corners 368 of the gate trenches 360.

Referring to FIG. 5D, an additional process may optionally be performed to further round the lower corners 366 of the gate trenches 360 and to round (or further round) the upper corners 368 of the gate trenches 360. The process may comprise, for example, an annealing step in which the device is annealed in a hydrogen-containing environment at a temperature of, for example, between 1200-1600° C. Alternatively or additionally, the process may be a sacrificial oxidation process in which the device is annealed in an oxygen-containing environment at a temperature of, for example, between 1200-1600° C., which acts to convert exposed portions of the semiconductor layer structure 350 into silicon oxide to a depth determined by the temperature, pressure and length of the annealing step, and the device is then etched using an etchant that selectively removes silicon oxide from silicon carbide. This etch will further round both the lower and upper corners 366, 368 of the gate trenches 360.

Referring to FIG. 5E, the gate oxide layers 370 are formed in the gate trenches 360. The gate oxide layers 370 are conformally formed so that they follow the outline of the gate trenches 360. As a result, the rounding of the lower and upper corners 366, 368 of the gate trenches 360 is replicated in the gate oxide layers 370 so that the gate oxide layers 370 also have rounded lower and upper corners 376, 378, as shown. As discussed above, this rounding reduces the electric field crowding effects, and hence may help reduce the peak electric field values in the gate oxide layers 370 during both on-state and reverse bias operation of the power MOSFET 300.

Gate electrodes 380 are then formed in the gate trenches 360 on the gate oxide layers 370. The gate electrodes 380 may be selectively formed in the gate trenches 360 by depositing the gate electrode material using a deposition mask (not shown) or may be blanket formed over the device and then planarization and/or etching processes may be used to remove the excess gate electrode material so that the gate electrodes 380 are only left in the respective gate trenches 360. The gate electrodes 380 are formed to extend upwardly to be no more than coplanar with the upper surface 352 of the semiconductor layer structure 350 and, more preferably, as recessed below the upper surface 352 of the semiconductor layer structure 350, as shown. In some example embodiments, the gate electrodes 380 may be recessed at least 0.01 microns, at least 0.2 microns, at least 0.5 microns, at least 1.0 microns or at least 2.0 microns below the upper surface 352 of the semiconductor layer structure 350. In the depicted embodiment, the gate electrodes 380 are recessed sufficiently so that an upper surface (in the active region 106) of the gate electrodes 380 are below the rounded upper corners 368 of the gate trenches 360.

Referring to FIG. 5F, an intermetal dielectric layer 384 is selectively formed on the gate electrodes 380. Next, the source contact 390 is formed over the active region of the device. The intermetal dielectric layer 384 isolates the gate electrodes 380 from the source contact 390.

FIG. 6 is a flow chart illustrating a method of fabricating a trench gate silicon carbide MOSFET according to embodiments of the present invention. As shown in FIG. 6. operations may begin with a semiconductor layer structure being provided (Block 400). As described above, the semiconductor layer structure may by formed by epitaxially growing a silicon carbide drift region on a silicon carbide substrate, and then forming other layers/regions in drift region such as silicon carbide well regions and source regions, a current spreading layer and/or trench shielding regions. Next, a mask may be formed on an upper surface of the semiconductor layer structure and the mask may be patterned to form a patterned mask that has openings over regions where gate trenches are to be formed in the upper surface of the semiconductor layer structure (Block 410).

Then, preliminary gate trenches may be formed in the upper surface of the semiconductor layer structure by etching the semiconductor layer structure (Block 420). The preliminary gate trenches have rounded lower corners. The upper corners of the preliminary gate trenches may be rounded or sharp corners, but if the upper corners are rounded, they may be rounded less than the lower corners. Next, one or more additional operations may optionally be performed to further round the lower corners of the preliminary gate trenches and to round the upper corners of the preliminary gate trenches, thereby converting the preliminary gate trenches into gate trenches (Block 430).

Then, gate oxide layers may be conformally formed in the respective gate trenches (Block 440). The gate oxide layers may extend onto the upper surface of the semiconductor layer structure and may have rounded lower corners and may optionally have rounded upper corners. Next, gate electrodes are formed in the respective gate trenches on the gate oxide layers, where each gate electrode is recessed so that an upper surface of the gate electrode is below the upper surface of the semiconductor layer structure (Block 450).

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on.” “connected to,” or “coupled to” another element or layer, it can be directly on, connected or coupled to the other element or layer, or intervening elements or layers may be present. In contrast, when an element is referred to as being “directly on.” “directly connected to,” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper.” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a silicon carbide based semiconductor layer structure that comprises an active region;
a gate trench in an upper portion of the semiconductor layer structure, the gate trench having a first rounded lower corner and a second rounded lower corner; and
a gate electrode in the gate trench,
wherein, within the active region, an upper surface of the gate electrode is below or coplanar with an upper surface of the semiconductor layer structure,
wherein the gate trench has a first rounded upper corner and a second rounded upper corner.

2. The semiconductor device of claim 1, wherein a radius of curvature of the first rounded lower corner exceeds a radius of curvature of the first rounded upper corner.

3. The semiconductor device of claim 1, wherein the upper surface of the gate electrode is below the upper surface of the semiconductor layer structure.

4. The semiconductor device of claim 1, wherein the upper surface of the gate electrode is below a midpoint of an arc defined by the first rounded upper corner.

5. The semiconductor device of claim 1, wherein the upper surface of the gate electrode is below a location where the first rounded upper corner has a smallest instantaneous angle.

6. The semiconductor device of claim 5, wherein the upper surface of the gate electrode is at least 0.1 microns below the location where the first rounded upper corner has the smallest instantaneous angle.

7. The semiconductor device of claim 1, wherein a radius of curvature of the first rounded lower corner is at least twice a radius of curvature of the first rounded upper corner.

8. The semiconductor device of claim 1, wherein the semiconductor layer structure further comprises a termination region that surrounds the active region, and the portion of the semiconductor layer in the active region comprises:
a drift region having a first conductivity type;
a plurality of well regions having a second conductivity type that is different from the first conductivity type on the drift region; and
a plurality of source regions having the first conductivity type, each source region in an upper portion of respective one of the well regions.

9. The semiconductor device of claim 8, further comprising:
a plurality of additional gate trenches in the upper surface of the semiconductor layer structure;
a plurality of additional gate electrodes in the respective plurality of additional gate trenches, where an upper surface of a portion of each additional gate electrode that is within the active region is below the upper surface of the semiconductor layer structure;
a gate dielectric layer in the gate trench between the gate electrode and the semiconductor layer structure; and
a plurality of additional gate dielectric layers in the respective additional gate trenches between the respective additional gate electrodes and the semiconductor layer structure.

10. The semiconductor device of claim 1, further comprising a gate dielectric layer in the gate trench between the gate electrode and the semiconductor layer structure,
wherein the semiconductor device is configured so that during on-state operation a peak electric field value in the gate dielectric layer will be located in a portion of the gate dielectric layer that is below the upper surface of the semiconductor layer structure.

11. (canceled)

12. A semiconductor device, comprising:
a silicon carbide based semiconductor layer structure that comprises an active region;
a gate trench in an upper portion of the semiconductor layer structure, the gate trench having a first rounded lower corner, a second rounded lower corner, a first rounded upper corner and a second rounded upper corner; and
a gate electrode in the gate trench,
wherein a respective radius of curvature of the first rounded lower corner exceeds a respective radius of curvature of the first rounded upper corner.

13. The semiconductor device of claim 12, wherein a first portion of the gate electrode is within the active region and a second portion of the gate electrode is outside the active region, and wherein an upper surface of the first portion of the gate electrode is below or coplanar with the upper surface of the semiconductor layer structure.

14. The semiconductor device of claim 13, wherein the upper surface of the gate electrode is below the upper surface of the semiconductor layer structure.

15. The semiconductor device of claim 12, wherein the upper surface of the first portion of the gate electrode is below a midpoint of an arc defined by the rounded upper corner of the gate trench.

16. (canceled)

17. The semiconductor device of claim 12, further comprising a gate dielectric layer in the gate trench between the gate electrode and the semiconductor layer structure,
wherein the semiconductor device is configured so that during on-state operation a peak electric field value in the gate dielectric layer will be located in a portion of the gate dielectric layer that is below the upper surface of the semiconductor layer structure.

18. A semiconductor device, comprising:
a silicon carbide based semiconductor layer structure that comprises an active region;
a gate trench in an upper portion of the semiconductor layer structure, the gate trench having a first rounded lower corner and a second rounded lower corner;
a gate electrode in the gate trench; and
a gate dielectric layer in the gate trench between the gate electrode and the semiconductor layer structure,
wherein the semiconductor device is configured so that a peak electric field in the gate dielectric layer during on-state operation is below an upper surface of the semiconductor layer structure.

19. The semiconductor device of claim 18, wherein an upper surface of the gate electrode is below the upper surface of the semiconductor layer structure.

20. The semiconductor device of claim 18, wherein a radius of curvature of the first rounded lower corner exceeds a radius of curvature of the second rounded upper corner.

21. (canceled)

22. The semiconductor device of claim 18, wherein an upper surface of the gate electrode is below a location where the first rounded upper corner has a smallest instantaneous angle.

23. (canceled)

24. The semiconductor device of claim 18, wherein a radius of curvature of the first rounded lower corner is at least twice a radius of curvature of the first rounded upper corner.

25-42. (canceled)
